(19) United States
(12) Patent Application Publication
(10) Pub. No.: US 2015/0034471 A1
(43) Pub. Date: Feb. 5, 2015

(54) KEYBOARD HAVING TACTILE FEEDBACK

(71) Applicants: DARFON ELECTRONICS (SUZHOU) CO., LTD., Suzhou (CN); DARFON ELECTRONICS CORP., Taoyuan (TW)

(72) Inventors: Shana Shiang-Fong Smith, Taoyuan (TW); Chien-Min Wu, Taoyuan (TW); Chih-Wen Hsu, Taoyuan (TW); Tzu-Kuei Lee, Taoyuan (TW); Huang-Hsiao Kao, Taoyuan (TW); Chih-An Wang, Taoyuan (TW); Fei-Ya Chen, Taoyuan (TW)

(21) Appl. No.: 14/446,336

(22) Filed: Jul. 30, 2014

(30) Foreign Application Priority Data
Jul. 31, 2013 (TW) 102127485

(51) Int. Cl. H01H 13/85; H01L 41/09

(52) U.S. Cl. CPC H01H 13/85; H01L 41/09
USPC 200/5 A

(57) ABSTRACT

A keyboard capable of generating a tactile feedback signal makes use of acceleration change of pressing behavior and releasing behavior of a physical keyswitch during pressing and releasing stages. The acceleration change is modulated according to a touch sensitive frequency response in various ways so that a simulated tactile feedback may be generated on the keyswitches of the keyboard.

### BACKGROUND OF THE INVENTION

1. Field of the Invention

The invention relates to a keyboard, and more particularly, to a keyboard that can generate a tactile feedback signal that simulates a physical keyswitch.

2. Description of the Prior Art

Keyboard has been significantly reduced in height with the trend of thin keyboard's development. The structure of the traditional mechanical buttons with a larger stroke has been difficult to be applied to such keyboard and therefore most thin keyboards use keyswitches with small stroke or touch button design. However, whether it is a small stroke keyswitch or a touch keyswitch, it is difficult for a user to sense the feedback when pressing the keyswitch, which makes the user having difficulty knowing whether or not the pressing operation of the keyswitch is completed, which results in some trouble in operation. Additionally, keyboards are provided nowadays equipped with vibrator in order to provide the user the tactile feedback. However, such type of vibrator is designed to provide only limited monotonous vibration feedback and is incapable of providing a clear sense of the key pressing. Also, the vibrator is an additional component, which adds thickness to the original keyswitch structure, contrary to the thin keyboard trend.

### SUMMARY OF THE INVENTION

In view of the above mentioned problem, one of the objectives of the invention aims at providing a method of generating a feedback signal on a keyboard with keyswitches without tactile feedback and applying such method on keyboards such as a piezoelectric keyboard, giving that thin keyboards may not only excel in its thin size but also provide tactile feedback equivalent as a mechanical keyboard or a membrane keyboard.

According to an embodiment of the invention, a keyboard is provided, which includes a keyswitch and a processor. The keyswitch includes a piezoelectric actuator. The processor stores a first vibration feedback signal and outputs the first vibration feedback signal to the piezoelectric actuator for generating vibration when the keyswitch is during the course change from a released status to a pressed status. The first vibration feedback signal is generated based on a periodic signal, and the frequency of the periodic signal is between 100˜500 Hz which is within a sensitive physiological tactile vibration frequency range, so that the first vibration feedback signal is detected by a user's fingertip.

Another embodiment of the invention provides a keyboard having tactile feedback. The keyboard includes a keyswitch, an actuator positioned near the keyswitch, and a processor. The processor stores a press feedback signal and outputs the press feedback signal to drive the actuator to generate a press vibration transmitted to the keyswitch when the keyswitch is during the course change from a released status to a pressed status. The press feedback signal includes a first interval waveform having a first maximal amplitude toward a first direction, a second interval waveform having a second maximal amplitude toward a second direction that is opposite to the first direction, and a third interval waveform having a third maximal amplitude toward the first direction. The second maximal amplitude is larger than the first maximal amplitude and the third maximal amplitude is larger than the second maximal amplitude.

Another embodiment of the invention provides a keyboard having tactile feedback. The keyboard includes a keyswitch, an actuator positioned near the keyswitch, and a processor. The processor stores a press feedback signal and outputs the press feedback signal to drive the actuator to generate a press vibration transmitted to the keyswitch when the keyswitch is during the course change from a released status to a pressed status, wherein the press feedback signal is generated from an operational combination of a press model waveform and a periodic signal whose frequency is between 100˜500 Hz. The press model waveform includes a first interval waveform having a fixed first predetermined amplitude, a second interval waveform having a fixed second predetermined amplitude, and a third interval waveform having a fixed third predetermined amplitude. The second predetermined amplitude is larger than the first predetermined amplitude and the third predetermined amplitude is smaller than the first predetermined amplitude.

Another embodiment of the invention provides a keyboard having tactile feedback. The keyboard includes a keyswitch, an actuator positioned near the keyswitch, and a processor. The processor stores a press feedback signal and outputs the press feedback signal to drive the actuator to generate a press vibration transmitted to the keyswitch when the keyswitch is during the course change from a released status to a pressed status, wherein the press feedback signal is generated from an operational combination of a press model waveform and a periodic signal whose frequency is between 100˜500 Hz. The press model waveform includes a first interval waveform having a first maximal amplitude, a second interval waveform having a second maximal amplitude, and a third interval waveform having a third maximal amplitude. The second maximal amplitude is larger than the first maximal amplitude and the third maximal amplitude is larger than the second maximal amplitude.

The keyboard having tactile feedback provided in the embodiments of the invention is capable of providing a tactile feedback equivalent to a mechanical keyswitch or a membrane keyswitch for a thin keyboard with small stroke keyswitches or touch keyswitches. Both light and thin dimension and good operation experience may be provided on the keyboard.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an illustration of a flow chart showing a method of generating a feedback signal on a keyboard according to the invention.

FIG. 2 is an illustration showing the relation of the force and stroke of an elastic piece with tactile feedback during pressing and releasing.

FIG. 3 is an illustration of a functional block diagram of a keyboard according to the invention.

FIG. 4 is an illustration of waveform of the vibration feedback signal generated according to a first embodiment of the invention.

FIG. 5 is an illustration of waveform of the vibration feedback signal generated according to a third embodiment of the invention.

FIG. 6 is an illustration showing the press model waveform and the release model waveform according to the third embodiment.

FIGS. 7-9 are illustrations of waveforms of the vibration feedback signal generated according to fifth to seventh embodiments of the invention.

### DETAILED DESCRIPTION

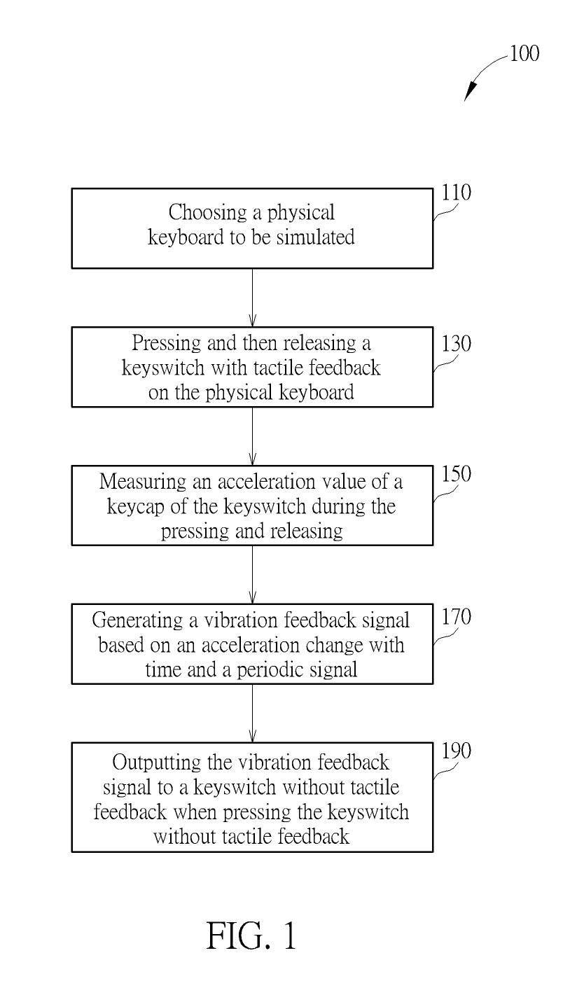

Please refer to FIG. 1. FIG. 1 is an illustration of a flowchart showing a method of generating a feedback signal on a keyboard according to the invention. The method 100 includes the steps of:

Step 110: choosing a physical keyboard to be simulated, which comes with elastic pieces with tactile feedback;

Step 130: pressing and then releasing a keyswitch with tactile feedback on the physical keyboard;

Step 150: measuring an acceleration value of a keycap of the keyswitch during the course change between a pressed status and a released status;

Step 170: generating a vibration feedback signal based on an acceleration change with time and a periodic signal;

Step 190: outputting the vibration feedback signal to a keyswitch without tactile feedback when pressing the keyswitch without tactile feedback.

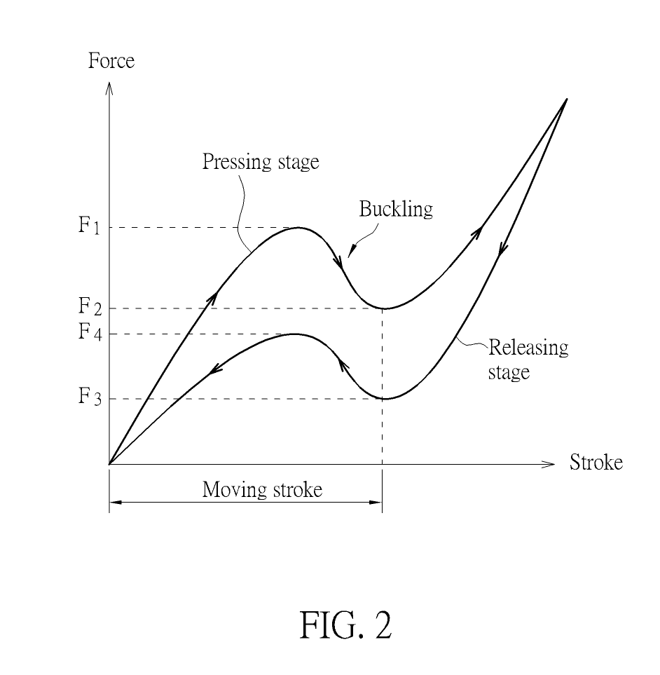

The first three steps of the method 100, Steps 110˜150, aim at collecting data of acceleration of the keycap from a real pressing and then releasing a single keyswitch with tactile feedback. In Step 110, a membrane switch keyboard or a mechanical keyboard is chose as a physical keyboard to be simulated. Such keyswitch comes with elastic piece with tactile feedback such as a rubber dome, a metal dome, or any type of elastic piece with tactile feedback during deformation. As the keyswitch is pressed by a user, the restoring force provided by the elastic piece presents a tactile feedback. Please refer to FIG. 2, which is an illustration showing the relation of the force and stroke of an elastic piece with tactile feedback during pressing and releasing. As shown in FIG. 2, in the process of moving downward as the keycap is pressed, the elastic piece with tactile feedback buckles when subjected with force larger than the Peak Force F1, at which moment the keycap rapidly declines until it touches the bottom plate, subjected now with a force called the Contact Force F2. As the force exerted to the keycap begins to vanish, the elastic piece will be first released from compression until the force gets back to the Return Force F3, and the elastic piece further rebounds back to the Return Peak Force F4 and then restores to the original status in a nearly linear way. It can be seen from FIG. 2 that the restoring force provided by the elastic piece with tactile feedback comes with a duration of change of gradually increase before gradually decrease.

Next in Step 130, press and release one of the keyswitches with tactile feedback on the physical keyboard. The Step 130 can be carried out by using a mechanical device that uses press force close to a human finger to simulate the action of pressing and releasing the keyswitch by the human finger. In Step 150, when the mechanical device presses and then releases the keyswitch, an acceleration value of the keycap is measured from the press stage and the release stage. For example, a laser interferometer may be used to record the displacement or the velocity of the keycap at various times when the keycap is pressed and then released. The measured velocity data is differentiated (or the displacement data is twice differentiated) to output a relation between the acceleration and time, or the acceleration change with time. The acceleration change of the keyswitch measured and operated in Step 150 stands for the change of a combination of (a) the pressing force downward by the user's finger and (b) the rebound force of the click sense elastic piece, when the keyswitch with tactile feedback is pressed and released.

As the R receptors (Ruffini ending) in the human fingertip have physiological sensitive tactile vibration frequencies between 100˜500 Hz, which is within a sensitive physiological tactile vibration frequency range, these frequency result will be included in consideration when designing the tactile feedback signal of the keyswitches. As described in step 170, the measured acceleration value according to Step 150 indicates an acceleration change with time, and such acceleration change is further modulated with a periodic signal to generate a vibration feedback signal. The vibration feedback signal will be transmitted to the keyswitch without tactile feedback when such keyswitch, a piezoelectric keyswitch for example, is physically pressed. User who uses his/her fingertip to press such keyswitch without tactile feedback can experience a sense of physical feedback force close to what a mechanical keyswitch or a membrane keyswitch may provide, as shown in step 190.

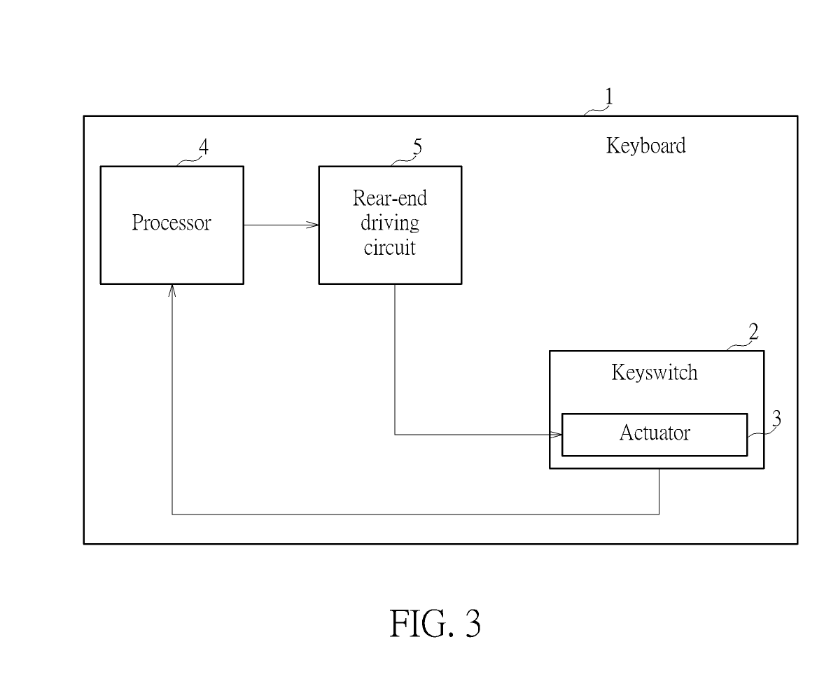

Please refer to FIG. 3. FIG. 3 is an illustration of a functional block diagram of a keyboard according to the invention. The keyboard 1 is a thin keyboard with small stroke or touch keyswitches 2. Not enough height and space are provided underneath for accommodating conventional elastic piece with tactile feedback. The keyswitch 2 includes an actuator 3, which may be a piezoelectric actuator or an artificial muscle actuator. Therefore, the keyboard 1 may be a piezoelectric keyboard or a keyboard having tactile feedback using artificial muscle as the source of feedback force. The actuator 3 may also be independently configured not being a part of the keyswitch 2 and positioned near the keyswitch 2 so as to provide a proper force feedback vibration. The keyboard 1 further includes a processor 4, a rear-end driving circuit 5, which are configured to be connected as shown in FIG. 3. As the method 100 in FIG. 1 describes, the processor 4 stores the vibration feedback signal generated in Step 170, which will be outputted by the processor 4 to the rear-end driving circuit 5 as the keyswitch 2 is pressed and the sensing circuit of the keyswitch 2 is triggered. The vibration feedback signal is then converted into an analog signal by the rear-end driving circuit 5, level adjusted and amplified, and then outputted to the actuator 3 to drive the actuator 3 to generate a simulated vibration according to the received signal. In other embodiment, the processor 5 directly converts the vibration feedback signal into the analog signal, level-adjusting and amplifying the analog signal, without the need of configuring the rear-end driving circuit 5, and outputs the signal to the actuator 3. In such way, the user may feel a simulated tactile feedback from the keyswitch with his/her fingertip when he/she presses the keyswitch.

As earlier described, Step 170 of FIG. 1 shows that the vibration feedback signal is generated based on the acceleration change and the periodic signal. To be more specific, the vibration feedback signal is generated by directly using the acceleration change or based on the acceleration change modulated with the periodic signal, by multiplication, addition, or subtraction. Several embodiments are provided in the following paragraphs describing the way of generating the vibration feedback signal. The acceleration change measured in Step 150 will be represented by A, the periodic signal represented by H, which is a sinusoidal wave with fixed amplitude and fixed frequency, or the fingertip sensitive physiological tactile vibration frequency as described, and the vibration feedback signal will be represented by C.

### The First Embodiment

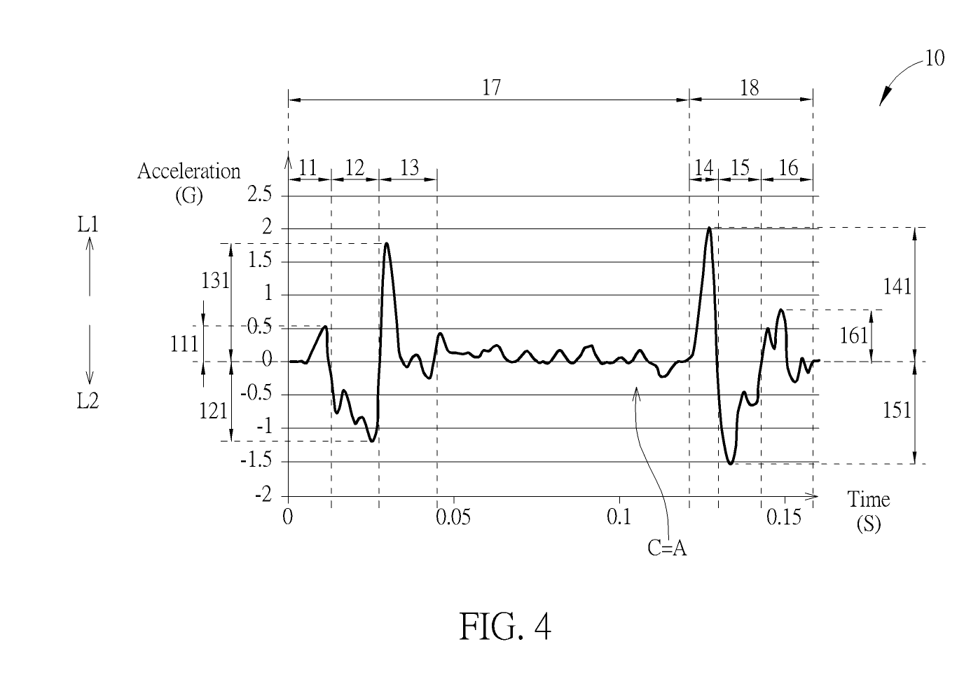

Please refer to FIG. 4. FIG. 4 is an illustration of waveform of the vibration feedback signal generated according to a first embodiment of the invention. In FIG. 4, the waveform 10 of the first embodiment only contains the acceleration change A measured in Step 150, which means the acceleration change A is directly used as the first type waveform 10 and the vibration feedback signal for driving the actuator 3, C=A. In FIG. 4, the vibration feedback signal C is stored in the processor 4 and can be further divided into a first vibration feedback signal 17 and a second vibration feedback signal 18, i.e., the acceleration change A can be divided into a first acceleration change of the pressing stage and a second acceleration change of a releasing stage. When the user presses the keyswitch 2, in the pressing stage, the processor 4 outputs the first vibration feedback signal 17 to the actuator 3 to generate a press vibration transmitted to the keyswitch 2 when the keyswitch 2 is during the course change from a released status to a pressed status. In the releasing stage, the processor 4 outputs the second vibration feedback signal 18 to the actuator 3 and driving the actuator 3 to generate a release vibration transmitted to the keyswitch 2 when the keyswitch 2 is during the course change from the pressed status to the released status.

More specifically, in the embodiment as shown in FIG. 3, the first vibration feedback signal 17 includes a first interval waveform 11, a second interval waveform 12, and a third interval waveform 13. The first interval waveform 11 has a first maximal amplitude 111 toward a first direction L₁, the second interval waveform 12 has a second maximal amplitude 121 toward a second direction L₂ and it can be seen from the figure that the first direction L₁ and the second direction L₂ are opposite to each other. Additionally, the second maximal amplitude 121 is larger than the first maximal amplitude 111. The third interval waveform 13 has a third maximal amplitude 131 to the same direction as the first maximal amplitude 111, the first direction L₁, and the third maximal amplitude 131 is larger than the second maximal amplitude 121.

The second vibration feedback signal 18 includes a fourth interval waveform 14, a fifth interval waveform 15, and a sixth interval waveform 16. The fourth interval waveform 14 includes a fourth maximal amplitude 141 toward the first direction L₁, the fifth interval waveform 15 includes a fifth maximal amplitude 151 toward the second direction L₂, and the fourth maximal amplitude 141 is larger than the fifth maximal amplitude 151. The sixth interval waveform 16 includes a sixth maximal amplitude 161 toward the first direction L₁, and the fifth maximal amplitude 151 is larger than the sixth maximal amplitude 161.

### The Second Embodiment

The internal storage space of the processor 4 may be less consumed via storing in the processor 4 only the first vibration feedback signal 17, including the first interval waveform 11, the second interval waveform 12, and the third interval waveform 13, whereas the second vibration feedback signal 18 in the first embodiment, including the fourth interval waveform 14, the fifth interval waveform 15, and the sixth interval waveform 16, is abandoned and not stored in the processor 4. In such way, when the user presses the keyswitch 2, in the pressing stage, the processor 4 outputs the first vibration feedback signal 17 to the actuator 3 to generate a press vibration transmitted to the keyswitch 2 when the keyswitch 2 is during the course change from the released status to the pressed status. In the releasing stage, the processor 4 outputs the first vibration feedback signal 17 again to the actuator 3 to drive the actuator 3 to generate the press vibration again for the keyswitch 2 when the keyswitch 2 is during the course change from the pressed status to the released status. The processor 4 may just output the first vibration feedback signal 17 to the actuator 3 in the pressing stage and not output any signal in the releasing stage.

### The Third Embodiment

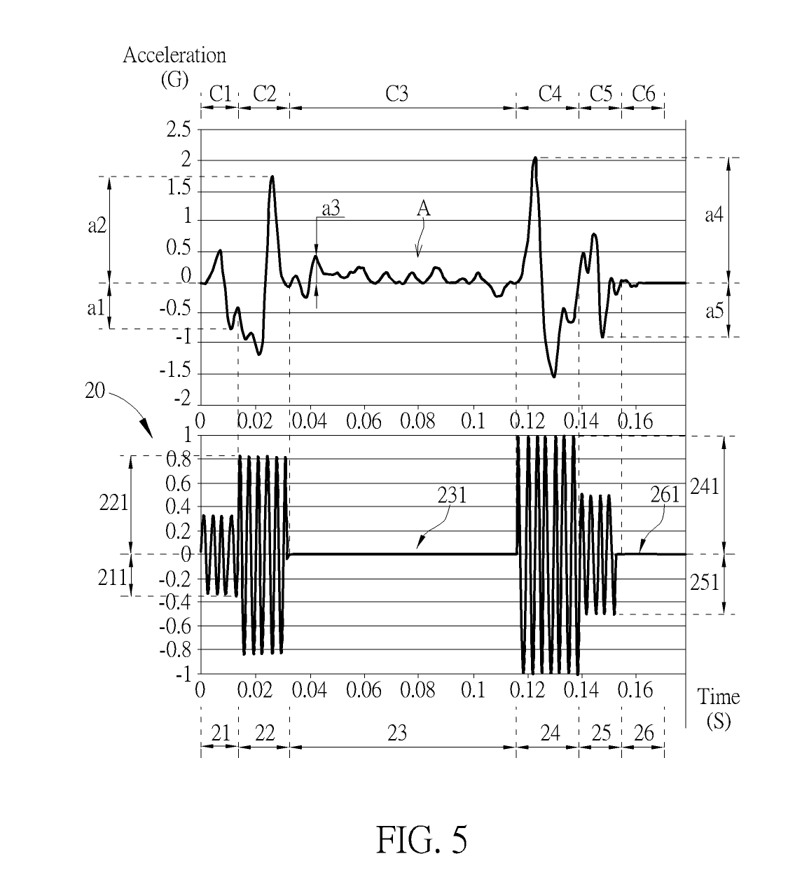

Please refer to FIG. 5. FIG. 5 is an illustration of waveform of the vibration feedback signal generated according to a third embodiment of the invention. In FIG. 5, the vibration feedback signal C of the waveform 20 of the third embodiment is generated based on a press model waveform and a release model waveform modulated by the periodic signal H, or the operational combination of the waveform and the periodic signal H.

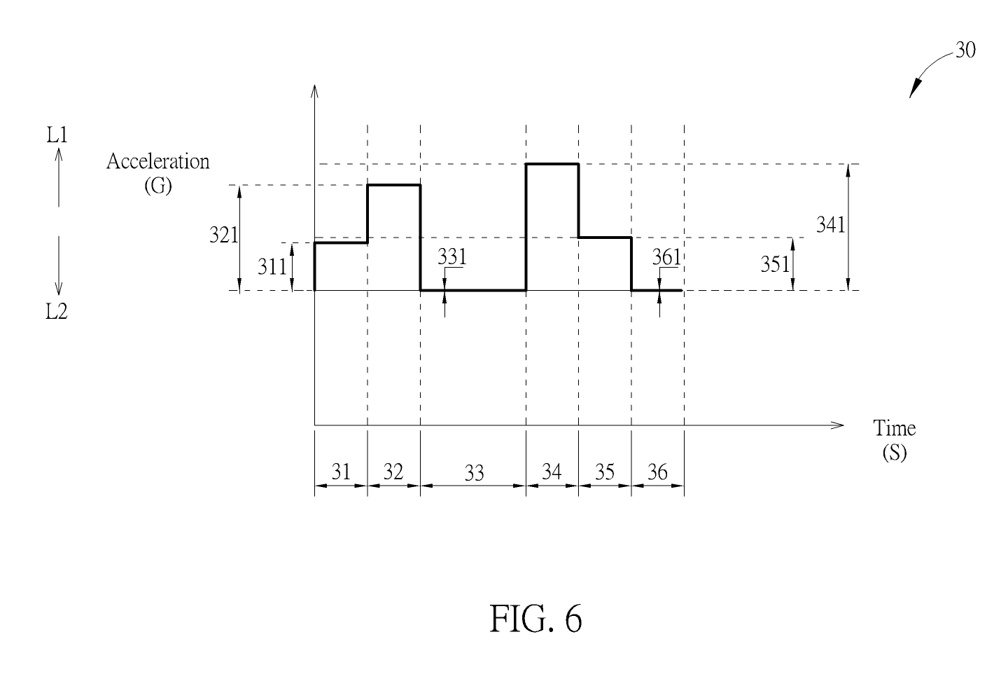

Please refer to FIG. 6. FIG. 6 is an illustration showing the press model waveform and the release model waveform. The way of generating the press model waveform and the release model waveform is described as followed: The upper half of FIG. 5 is the acceleration change A, including a plurality of sections C1˜C6. Taking the direction of acceleration into consideration, the sectional maximal acceleration absolute value of each of the sections C1˜C2, C4˜C5 can be determined. The first section C1 has a sectional maximal acceleration absolute value a1, the second section C2 has a sectional maximal acceleration absolute value a2, the fourth section C4 has a sectional maximal acceleration absolute value a4, and the fifth section C5 has a sectional maximal acceleration absolute value a5. It should be noted that the third section C3 stands for the time section when the finger is pressing the keycap down to the bottommost position and the sixth section C6 stands for the time section when the finger releases the keycap up to the topmost position. Although a sectional maximal acceleration absolute value a3 can be measured due to local interfering signal in the third section C3, practically the sectional maximal acceleration absolute values of the third section C3 and the sixth section C6 are set to be 0. In all these sections, a maximal acceleration absolute value is defined as ‘a’ and ‘a’=max(a1, a2, a3, a4, a5), which in this embodiment, ‘a’=a4. Next, the ratio h of each sectional maximal acceleration absolute value to the maximal acceleration absolute value ‘a’ can be obtained. Taking the upper half of FIG. 4 as an example:

Ratio of the first section C1: h1=a1/a=0.77/2.03=0.38;

Ratio of the second section C2: h2=a2/a=1.74/2.03=0.86;

Ratio of the third section C3: h3=0; (finger is pressing the keycap down to the bottommost position with acceleration 0)

Ratio of the fourth section C4: h4=a4/a=2.03/2.03=1;

Ratio of the fifth section C5: h5=a5/a=0.9/2.03=0.45;

Ratio of the sixth section C6: h6=0; (finger is releasing the keycap up to the topmost position with acceleration 0).

After the calculation above, the press model waveform (C1˜C3) and the release model waveform (C4˜C6) as shown in FIG. 5 may be obtained. The press model waveform includes a first interval waveform 31 having a fixed first predetermined amplitude 311, a second interval waveform 32 having a fixed second predetermined amplitude 321, and a third interval waveform 33 having a fixed third predetermined amplitude 331. The second predetermined amplitude 321 is larger than the first predetermined amplitude 311 and the third predetermined amplitude 331 is smaller than the first predetermined amplitude 311. The release model waveform includes a fourth interval waveform 34 having a fixed fourth predetermined amplitude 341, a fifth interval waveform 35 having a fixed fifth predetermined amplitude 351, and a sixth interval waveform 36 having a fixed sixth predetermined amplitude 361. The fifth predetermined amplitude 351 is smaller than the fourth predetermined amplitude 341 and the sixth predetermined amplitude 261 is smaller than the fifth predetermined amplitude 351.

The press model waveform and the release model waveform are further operated and combined with the periodic signal H. Specifically, the interval waveform of each section is established from the periodic signal H multiplied by the ratio of each section. It can be seen from the lower half of FIG. 5 that the first interval waveform 21 has a fixed first predetermined amplitude 211, the second interval waveform 22 has a fixed second predetermined amplitude 221, the third interval waveform 23 has a fixed third predetermined amplitude 211, which is 0, the fourth interval waveform 24 has a fixed fourth predetermined amplitude 241, the fifth interval waveform 25 has a fixed fifth predetermined amplitude 251, and the sixth interval waveform 26 has a fixed sixth predetermined amplitude 261, which is also 0. Each interval waveform has frequency as the frequency of the periodic signal H and the vibration feedback signal C of the third type waveform is the combination of the waveform of each section, i.e., C=21+22+23+24+25+26.

The waveform 20 in the third embodiment is an operational combination of the acceleration change A and the fingertip sensitive periodic signal H, with the principle of simulation:

(1) dividing the course of pressing the keyswitch into three time sections: (a) the deformation stage of the rubber dome with tactile feedback before it buckles; (b) the deformation stage after the rubber dome buckles; (c) the keycap keeps being pressed down to the bottommost position;

(2) dividing the course of releasing the keyswitch into three time sections: (a) the deformation of the buckled rubber dome with tactile feedback; (b) the deformation stage after the buckling of the rubber dome with tactile feedback vanishes; (c) the keycap keeps being released to the topmost position;

(3) Under the condition of same frequency, the amplitude of the vibration of the actuator 3 is proportional to the sectional maximal acceleration absolute value of the time section.

In such way, simulation of the magnitude of the feedback force in each time section accomplished by changing the amplitude of the waveform in each time section applying on the actuator 3.

### The Fourth Embodiment

The internal storage space of the processor 4 may be less consumed via storing in the processor 4 only the press model waveform, including the first section C1, the second section C2, and the third section C3. In other words, when the user presses the keyswitch 2, in the pressing stage, the processor 4 outputs a press feedback signal (=21+22+23) to the actuator 3 to generate a press vibration transmitted to the keyswitch 2 when the keyswitch 2 is during the course change from the released status to the pressed status. In the releasing stage, the processor 4 outputs the press feedback signal again to the actuator 3 to drive the actuator 3 to generate the press vibration again for the keyswitch 2 when the keyswitch 2 is during the course change from the pressed status to the released status. Users may experience same vibration feedback either in the pressing stage or in the releasing stage. Besides, the processor 4 may just output the press feedback signal to the actuator 3 in the pressing stage and not output any signal in the releasing stage.

### The Fifth Embodiment

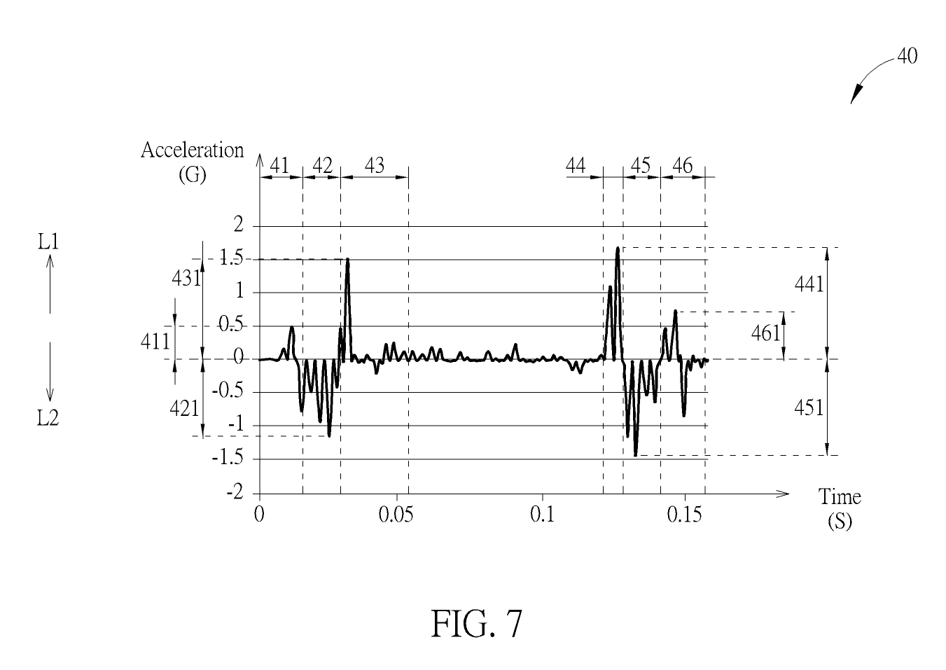

Please refer to FIG. 7. FIG. 7 is an illustration of waveform of the vibration feedback signal generated according to a fifth embodiment of the invention. The vibration feedback signal C of the waveform 40 in the fifth embodiment is also generated based on the acceleration change A modulated with the periodic signal C, by multiplication, addition, or subtraction. As an exemplary embodiment, the acceleration change A in FIG. 7 is multiplied by the periodic signal H to generate the vibration feedback signal C, i.e., C=A*H, whereas the vibration feedback signal C can further be divided into a first vibration feedback signal in the pressing stage and a second vibration feedback signal in the releasing stage.

The first vibration feedback signal includes a first interval waveform 41, a second interval waveform 42, and a third interval waveform 43. The first interval waveform 41 has a first maximal amplitude 411, the second interval waveform 42 has a second maximal amplitude 421, and the third interval waveform 43 has a third maximal amplitude 431. The second maximal amplitude 421 is larger than the first maximal amplitude 411 and the third maximal amplitude 431 is larger than the second maximal amplitude 421.

The second vibration feedback signal includes a fourth interval waveform 44, a fifth interval waveform 45, and a sixth interval waveform 46. The fourth interval waveform 44 has a fourth maximal amplitude 441, the fifth interval waveform 45 has a fifth maximal amplitude 451, and the sixth interval waveform. 46 has a sixth maximal amplitude 461. The fifth maximal amplitude 451 is smaller than the fourth maximal amplitude 441 and the sixth maximal amplitude 461 is smaller than the fifth maximal amplitude 451.

In the waveform 40 of the fifth embodiment, the first maximal amplitude 411, the third maximal amplitude 431, the fourth maximal amplitude 441, and the sixth maximal amplitude 461 are toward a first direction L₁, and the second maximal amplitude 421 and the fifth maximal amplitude 451 are toward a second direction L₂ opposite to the first direction L₁.

### The Sixth Embodiment

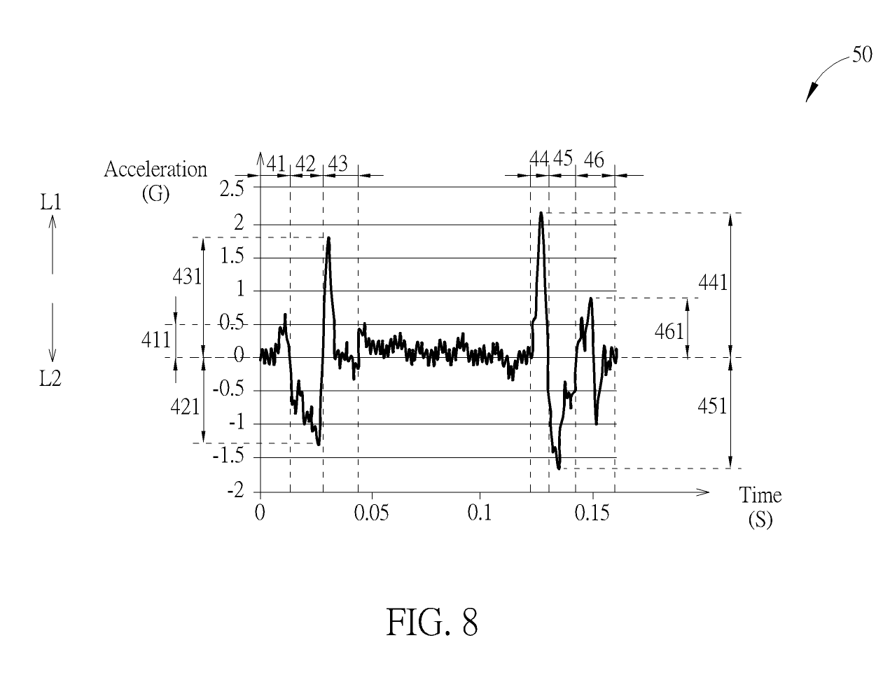

Please refer to FIG. 8 for a vibration feedback signal C generated in a similar way as the waveform 40 of the fifth embodiment. The vibration feedback signal C of the waveform 50 of the sixth embodiment in FIG. 8 is generated based on the acceleration change A subtracted by the periodic signal H, i.e., C=A-H.

### The Seventh Embodiment

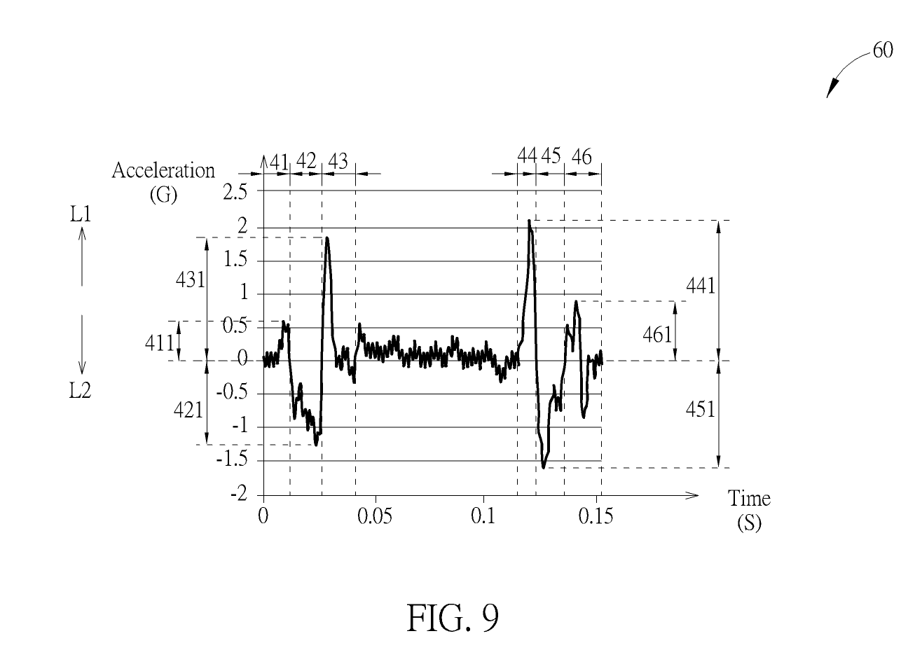

Please refer to FIG. 9 for a vibration feedback signal C generated in a similar way as the waveform 40 of the fifth embodiment. The vibration feedback signal C of the waveform 60 of the seventh embodiment in FIG. 9 is generated based on the acceleration change A added by the periodic signal H, i.e., C=A+H.

Similarly, the internal storage space of the processor 4 may be less consumed via storing in the processor 4 only the first vibration feedback signal in the fifth, sixth, seventh embodiments, including the first three interval waveforms, whereas the second vibration feedback signal in the fifth, sixth, seventh embodiments, including the last three interval waveforms, are abandoned and not stored in the processor 4. In such way, when the user presses the keyswitch 2, in the pressing stage, the processor 4 outputs the first vibration feedback signal, for the first time, to the actuator 3. In the releasing stage, the processor 4 outputs the first vibration feedback signal, for the second time, to the actuator 3. Besides, the processor 4 may just output the first vibration feedback signal to the actuator 3 in the pressing stage and not output any signal in the releasing stage.

From each embodiment described above, the keyboard capable of generating a feedback signal makes use of acceleration change of pressing behavior and releasing behavior of a physical keyswitch during pressing and releasing stages to establish the press model waveform and the release model waveform. The fingertip sensitive physiological tactile vibration frequency is further incorporated to develop a variety of operational combinations so as to provide an effect of real simulation of tactile feedback when pressing the keyswitch without tactile feedback.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A keyboard, comprising:
a keyswitch comprising a piezoelectric actuator; and
a processor storing a first vibration feedback signal, the processor outputting the first vibration feedback signal to the piezoelectric actuator for generating vibration when the keyswitch is during the course change from a released status to a pressed status;
wherein the first vibration feedback signal is generated based on a periodic signal, the frequency of the periodic signal being between 100˜500 Hz which is within a sensitive physiological tactile vibration frequency range, so that the first vibration feedback signal is detected by a user's fingertip.

2. The keyboard of claim 1, wherein a first acceleration change is measured from a keyswitch with tactile feedback which is in the course change from the released status to the pressed status, and the first vibration feedback signal is generated based on the operational result of the periodic signal and the first acceleration change.

3. The keyboard of claim 2, wherein the first vibration feedback signal is generated based on the periodic signal modulating the first acceleration change.

4. The keyboard of claim 1, wherein the processor further stores a second vibration feedback signal, the processor outputting the second vibration feedback signal to the piezoelectric actuator for generating vibration when the keyswitch is during the course change from the pressed status to the released status.

5. The keyboard of claim 4, wherein a second acceleration change is measured from a keyswitch with tactile feedback which is in the course change from the pressed status to the released status, and the second vibration feedback signal is generated based on the operational result of the periodic signal and the second acceleration change.

6. A keyboard having tactile feedback, comprising:
a keyswitch;
an actuator positioned near the keyswitch; and
a processor storing a press feedback signal, the processor outputting the press feedback signal to drive the actuator to generate a press vibration transmitted to the keyswitch when the keyswitch is during the course change from a released status to a pressed status;
wherein the press feedback signal comprises:
a first interval waveform comprising a first maximal amplitude toward a first direction;
a second interval waveform comprising a second maximal amplitude toward a second direction that is opposite to the first direction, wherein the second maximal amplitude is larger than the first maximal amplitude; and
a third interval waveform comprising a third maximal amplitude toward the first direction, wherein the third maximal amplitude is larger than the second maximal amplitude.

7. The keyboard having tactile feedback of claim 6, wherein the processor further stores a release feedback signal, the processor outputting the release feedback signal to drive the actuator to generate a release vibration transmitted to the keyswitch when the keyswitch is during the course change from the pressed status to the released status;
wherein the release feedback signal comprises:
a fourth interval waveform comprising a fourth maximal amplitude toward the first direction;
a fifth interval waveform comprising a fifth maximal amplitude toward the second direction, wherein the fourth maximal amplitude is larger than the fifth maximal amplitude; and
a sixth interval waveform comprising a sixth maximal amplitude toward the first direction, wherein the fifth maximal amplitude is larger than the sixth maximal amplitude.

8. The keyboard having tactile feedback of claim 6, wherein the processor outputs the press feedback signal to drive the actuator to generate the press vibration again when the keyswitch is during the course change from the pressed status to the released status .

9. The keyboard having tactile feedback of claim 6, wherein the actuator is a piezoelectric actuator or an artificial muscle actuator.

10. A keyboard having tactile feedback, comprising:
a keyswitch;
an actuator positioned near the keyswitch; and
a processor storing a press feedback signal, the processor outputting the press feedback signal to drive the actuator to generate a press vibration transmitted to the keyswitch when the keyswitch is during the course change from a released status to a pressed status;
wherein the press feedback signal is generated from an operational combination of a press model waveform and a periodic signal whose frequency is between 100˜500 Hz, the press model waveform comprising:
a first interval waveform comprising a fixed first predetermined amplitude;
a second interval waveform comprising a fixed second predetermined amplitude, wherein the second predetermined amplitude is larger than the first predetermined amplitude ; and
a third interval waveform comprising a fixed third predetermined amplitude, wherein the third predetermined amplitude is smaller than the first predetermined amplitude.

11. The keyboard having tactile feedback of claim 10, wherein the processor further stores a release feedback signal, the processor outputting the release feedback signal to drive the actuator to generate a release vibration transmitted to the keyswitch when the keyswitch is during the course change from the pressed status to the released status;
wherein the release feedback signal is generated from an operational combination of a release model waveform and the periodic signal, the release model waveform comprising:
a fourth interval waveform comprising a fixed fourth predetermined amplitude;
a fifth interval waveform comprising a fixed fifth predetermined amplitude, wherein the fifth predetermined amplitude is smaller than the fourth predetermined amplitude; and
a sixth interval waveform comprising a fixed sixth predetermined amplitude, wherein the sixth predetermined amplitude is smaller than the fifth predetermined amplitude.

12. The keyboard having tactile feedback of claim 10, wherein the processor outputs the press feedback signal to drive the actuator to generate a press vibration transmitted to the keyswitch when the keyswitch is during the course change from the pressed status to the released status.

13. The keyboard having tactile feedback of claim 10, wherein the actuator is a piezoelectric actuator or an artificial muscle actuator.

14. A keyboard having tactile feedback, comprising:
a keyswitch;
an actuator positioned near the keyswitch; and
a processor storing a press feedback signal, the processor outputting the press feedback signal to drive the actuator to generate a press vibration transmitted to the keyswitch when the keyswitch is during the course change from a released status to a pressed status;
wherein the press feedback signal is generated from an operational combination of a press model waveform and a periodic signal whose frequency is between 100˜500 Hz, the press model waveform comprising:
a first interval waveform comprising a first maximal amplitude;
a second interval waveform comprising a second maximal amplitude, wherein the second maximal amplitude is larger than the first maximal amplitude; and
a third interval waveform comprising a third maximal amplitude, wherein the third maximal amplitude is larger than the second maximal amplitude.

15. The keyboard having tactile feedback of claim 14, wherein the processor further stores a release feedback signal, the processor outputting the release feedback signal to drive the actuator to generate a release vibration transmitted to the keyswitch when the keyswitch is during the course change from the pressed status to the released status;
wherein the release feedback signal is generated from an operational combination of a release model waveform and the periodic signal, the release model waveform comprising:
a fourth interval waveform comprising a fourth maximal amplitude;
a fifth interval waveform comprising a fifth maximal amplitude, wherein the fifth maximal amplitude is smaller than the fourth maximal amplitude; and
a sixth interval waveform comprising a sixth maximal amplitude, wherein the sixth maximal amplitude is smaller than the fifth maximal amplitude.

16. The keyboard having tactile feedback of claim 15, wherein the first maximal amplitude, the third maximal amplitude, the fourth maximal amplitude, and the sixth maximal amplitude are toward a first direction, and the second maximal amplitude and the fifth maximal amplitude are toward a second direction opposite to the first direction.

17. The keyboard having tactile feedback of claim 15, wherein the processor outputs the press feedback signal to drive the actuator to generate a press vibration again when the keyswitch is during the course change from the pressed status to the released status.

18. The keyboard having tactile feedback of claim 14, wherein the actuator is a piezoelectric actuator or an artificial muscle actuator.
